(19) United States
(12) Patent Application Publication
(10) Pub. No.: US 2020/0074140 A1
(43) Pub. Date: Mar. 5, 2020

(54) FINGERPRINT IDENTIFICATION PANEL, FINGERPRINT IDENTIFICATION METHOD AND DISPLAY DEVICE

(71) Applicant: BOE TECHNOLOGY GROUP CO., LTD., Beijing (CN)

(72) Inventors: Changfeng LI, Beijing (CN); Xue DONG, Beijing (CN); Haisheng WANG, Beijing (CN); Xiaochuan CHEN, Beijing (CN); Yingming LIU, Beijing (CN); Xiaoliang DING, Beijing (CN); Lei WANG, Beijing (CN); Yunke QIN, Beijing (CN)

(21) Appl. No.: 16/491,953

(22) PCT Filed: Jan. 17, 2019
(86) PCT No.: PCT/CN2019/072087

§ 371 Date: Sep. 6, 2019

(30) Foreign Application Priority Data
May 17, 2018 (CN) 201810474253.0

(51) Int. Cl. G06K 9/00; G06F 3/042; H01L 27/32

(52) U.S. Cl. CPC G06K 9/0004; G06F 2203/04102; H01L 27/323; G06F 3/0421

(57) ABSTRACT

The present disclosure provides a fingerprint identification panel, a fingerprint identification method and a display device. The fingerprint identification panel includes: a display panel including a substrate and a display element arranged at one side of the substrate; and a fingerprint identification module arranged at a side of the substrate away from the display element. The fingerprint identification module includes a collimation membrane and photosensitive sensors. The collimation membrane is configured to allow a collimated light beam in a reflected light beam to pass therethrough and prohibit a scattered light beam in the reflected light beam from passing therethrough. The reflected light beam is formed by a light beam emitted from the display panel and reflected by a finger. Each photosensitive sensor is configured to receive the collimated light beam and identity a fingerprint in accordance with the collimated light beam.

### CROSS-REFERENCE TO RELATED APPLICATION

This application is the U.S. National phase of PCT Application No. PCT/CN2019/072087 filed on Jan. 17, 2019, which claims a priority to Chinese Patent Application No.201810474253.0 filed on May 17, 2018, the disclosures of which are incorporated in their entirety by reference herein.

### TECHNICAL FIELD

The present disclosure relates to the field of display technology, in particular to a fingerprint identification panel, a fingerprint identification method and a display device.

### BACKGROUND

During the manufacture of a flexible Organic Light-Emitting Diode (OLED) display panel in related art, a support plate is provided, a flexible base substrate is arranged on the support plate, and a driving circuit layer and light-emitting elements are arranged on the flexible base substrate. After the formation of the driving circuit layer and the light-emitting elements is completed, it is necessary to remove the flexible base substrate from the support plate, and then a polyethylene terephthalate (PET) film is attached to one side of the flexible base substrate, so as to prevent the flexible base substrate from shrinking in use process, and protect the OLED display panel.

### SUMMARY

In one aspect, the present disclosure provides in some embodiments a fingerprint identification panel, including: a display panel including a substrate and a display element arranged at one side of the substrate; and a fingerprint identification module arranged at a side of the substrate away from the display element. The fingerprint identification module includes a collimation membrane and photosensitive sensors. The collimation membrane is configured to allow a collimated light beam in a reflected light beam to pass therethrough and prohibit a scattered light beam in the reflected light beam from passing therethrough. The reflected light beam is formed by a light beam emitted from the display panel and reflected by a finger. Each photosensitive sensor is configured to receive the collimated light beam and identity a fingerprint in accordance with the collimated light beam.

In a possible embodiment of the present disclosure, the display panel is a flexible display panel, and the substrate is a flexible substrate.

In a possible embodiment of the present disclosure, the collimation membrane is reused as at least a part of the flexible substrate.

In a possible embodiment of the present disclosure, the flexible substrate includes a flexible base substrate and a support layer, and the collimation membrane is reused as the support layer or as the flexible base substrate and the support layer.

In a possible embodiment of the present disclosure, the flexible base substrate has a thickness of 15 μm to 25 μm, and the support layer has a thickness of 70 μm to 100 μm.

In a possible embodiment of the present disclosure, the flexible display panel further includes a thin film encapsulation layer covering the display element, a polarizer arranged at a side of the thin film encapsulation layer away from the display element, and an encapsulation cover plate arranged at a side of the polarizer away from the thin film encapsulation layer.

In a possible embodiment of the present disclosure, the fingerprint identification module further includes a flexible thin film. The photosensitive sensors are arranged on the flexible thin film in an array form, and the flexible thin film is attached to a side of the collimation membrane away from the flexible display panel.

In a possible embodiment of the present disclosure, the collimation membrane includes a plurality of light-shielding retainer walls, and a transparent material layer filled between two adjacent light-shielding retainer walls.

In a possible embodiment of the present disclosure, the plurality of light-shielding retainer walls is arranged in parallel with each other.

In a possible embodiment of the present disclosure, each of the plurality of light-shielding retainer walls is of a strip-like shape.

In a possible embodiment of the present disclosure, the transparent material layer has a height greater than or equal to a height of any light-shielding retainer wall.

In a possible embodiment of the present disclosure, a ratio of a distance between two adjacent light-shielding retainer walls to the height of each light-shielding retainer wall is 1/10 to 1/7.

In a possible embodiment of the present disclosure, the collimation membrane has a thickness of 100 μm to 300 μm.

In a possible embodiment of the present disclosure, the display panel is a non-flexible display panel.

In another aspect, the present disclosure provides in some embodiments a fingerprint identification method for the above-mentioned fingerprint identification panel, including: transmitting, by the display panel, a reflected light beam to a collimation membrane, the reflected light beam being formed by a light beam emitted from the display panel and reflected by a finger; allowing, by a collimation membrane, a collimated light beam in the reflected light beam to pass therethrough, and shielding a scattered light beam in the reflected light beam; and receiving, by a photosensitive sensor, the collimated light beam, and identifying a fingerprint in accordance with the collimated light beam.

In yet another aspect, the present disclosure provides in some embodiments a display device including the above-mentioned fingerprint identification panel.

### BRIEF DESCRIPTION OF THE DRAWINGS

FIG. 1 is a schematic view showing a fingerprint identification panel according to one embodiment of the present disclosure;

FIG. 2 is another schematic view showing the fingerprint identification panel according to one embodiment of the present disclosure;

FIG. 3 is a schematic view showing a collimation membrane in FIG. 2;

FIG. 4 is a schematic view showing section A in FIG. 3; and

FIG. 5 is yet another schematic view showing the fingerprint identification panel according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments.

During the manufacture of a flexible OLED display panel in related art, the flexible OLED display panel has a relatively large thickness due to the presence of a PET film. When the flexible OLED display panel is adopted for fingerprint identification, an optical path of a light beam reflected by each valley or ridge of a fingerprint may increase due to the large thickness of the flexible OLED display panel. When the optical path is too long, many scattered light beams may be generated, and thereby the fingerprint identification accuracy may be adversely affected.

An object of the present disclosure is to provide a fingerprint identification panel, a fingerprint identification method and a display device, so as to improve accuracy of fingerprint identification.

The present disclosure provides in some embodiments a fingerprint identification panel, including a display panel and a fingerprint identification module.

The display panel includes a substrate and a display element arranged on the substrate.

The fingerprint identification module is arranged at a side of the substrate away from the display element, and includes a collimation membrane and photosensitive sensors. The collimation membrane is configured to allow a collimated light beam in a reflected light beam to pass therethrough and prohibit a scattered light beam in the reflected light beam from passing therethrough. The reflected light beam is formed by a light beam emitted from the display panel and reflected by a finger. Each photosensitive sensor is configured to receive the collimated light beam and identity a fingerprint in accordance with the collimated light beam.

According to the embodiments of the present disclosure, the collimation membrane of the fingerprint identification module may allow the collimated light beam in the reflected light beam to pass therethrough and prohibit the scattered light beam in the reflected light beam from passing therethrough, and each photosensitive sensor may receive the collimated light beam passing through the collimation membrane and identify the fingerprint in accordance with the collimated light beam. As a result, it is able to improve accuracy of fingerprint identification.

In some embodiments of the present disclosure, the display panel may be a non-flexible display panel.

In some embodiments of the present disclosure, the display panel may be a flexible display panel, the substrate may be a flexible substrate, and the flexible display panel may include the flexible substrate and the display element arranged at one side of the flexible substrate.

In some embodiments of the present disclosure, when the display panel is the flexible display panel and the substrate is the flexible substrate, the collimation membrane may be reused as at least a part of the flexible substrate.

In the embodiments of the present disclosure, when the collimation membrane of the fingerprint identification module is reused as at least a part of the flexible substrate, the collimation membrane may function as a support so as to prevent the flexible display panel from shrinking. In addition, it is able to reduce a thickness of the fingerprint identification panel, reduce an optical path of a light beam reflected by each valley or ridge of the fingerprint, reduce the loss of information about the light beam reflected by the valley or ridge, and increase an intensity of the light beam received by the photosensitive sensor, thereby to improve accuracy of fingerprint identification.

In some embodiments of the present disclosure, the flexible substrate may include a flexible base substrate and a support layer, and the collimation membrane may be reused as the support layer.

In some embodiments of the present disclosure, during the manufacture of the flexible display panel, the flexible base substrate may be formed on a support plate, and the display element may be formed on the flexible base substrate. After the manufacture of the display element, the flexible base substrate may be removed off from the support plate. The support layer may be attached to a side of the flexible base substrate away from the display element. Through the collimation membrane (which is reused as the support layer), it is able to prevent the flexible base substrate from shrinking during the use thereof, and protect the flexible display panel.

In some embodiments of the present disclosure, the flexible substrate may include a flexible base substrate and a support layer, and the collimation membrane may be reused as the flexible base substrate and the support layer.

In some embodiments of the present disclosure, the flexible base substrate may be a polyimide (PI) film, and the support layer may be a PET film.

In some embodiments of the present disclosure, the collimation membrane may be reused as the support layer, the flexible base substrate may have a thickness of 15 μm to 25 μm, and the support layer may have a thickness of 70 μm to 100 μm (i.e., the collimation membrane may have a thickness of 70 μm to 100 μm).

In some embodiments of the present disclosure, the collimation membrane may be reused as the flexible base substrate and the support layer, the flexible base substrate may have a thickness of 15 μm to 25 μm, and the support layer may have a thickness of 70 μm to 100 μm (i.e., the collimation membrane may have a thickness of 85 μm to 125 μm).

The flexible substrate has a relatively large thickness, so when the flexible OLED display panel is adopted for fingerprint identification, the optical path of the light beam reflected by each valley or ridge of the fingerprint may be too long, a large quantity of scattered light beams may be generated, and thereby the fingerprint identification accuracy may be adversely affected. By providing the collimation membrane in the embodiments of the present disclosure, it is able to screen out the scattered light beams, thereby to improve accuracy of fingerprint identification.

When the collimation membrane is reused as the flexible base substrate and the support layer, as compared with the situation where the collimation membrane is merely reused as the support layer, it is able to reduce a thickness of the fingerprint identification panel, thereby to improve accuracy of fingerprint identification.

In some embodiments of the present disclosure, the flexible display panel may further includes a thin film encapsulation layer covering the display element, a polarizer arranged at a side of the thin film encapsulation layer away from the display element, and an encapsulation cover plate arranged at a side of the polarizer away from the thin film encapsulation layer.

Through the thin film encapsulation layer and the encapsulation cover plate, it is able to improve sealing of the flexible display panel, thereby to prevent moisture and oxygen from entering the display element.

In some embodiments of the present disclosure, the fingerprint identification module may further include a flexible thin film.

The photosensitive sensors may be arranged on the flexible thin film in an array form, and the flexible thin film may be attached to a side of the collimation membrane away from the flexible display panel. The flexible thin film may function as to support the photosensitive sensors.

As shown in FIG. 1, the fingerprint identification panel may include a flexible OLED display panel and a fingerprint identification module.

The fingerprint identification module may include a flexible thin film 1, photosensitive sensors 2 and a collimation membrane 3. The photosensitive sensors 2 may be arranged on the flexible thin film 1 in an array form. The collimation membrane 3 is configured to allow a collimated light beam in a reflected light beam (which is formed by a light beam emitted from the flexible OLED display panel and reflected by a finger) to pass therethrough and prohibit a scattered light beam in the reflected light beam from passing therethrough. Each photosensitive sensor 2 is configured to receive the collimated light beam and identify a fingerprint in accordance with the collimated light beam.

The flexible OLED display panel may include a flexible substrate and a display element arranged at one side of the substrate. The flexible substrate may include a flexible base substrate 4, a buffer layer 5 arranged at a side of the flexible base substrate 4, and a support layer (i.e., a PET film 23) arranged at a side of the flexible base substrate 4 away from the buffer layer 5.

The flexible OLED display panel may include a thin film transistor, a first insulation layer 6, a second insulation layer 7 and a third insulation layer 8 arranged at a side of the buffer layer 5 away from the flexible base substrate.

The thin film transistor may include an active layer 17, a gate electrode 18, a source electrode 19 and a drain electrode 20. The first insulation layer 6 may be arranged between the gate electrode 18 and the active layer 17, and the second insulation layer 7 and the third insulation layer 8 may be arranged between the source electrode 19 as well as the drain electrode 20 and the gate electrode 18.

The display element may include the buffer layer 5, the thin film transistor, the first insulation layer 6, the second insulation layer 7, the third insulation layer 8, a planarization layer 9, an anode 21, a pixel definition layer 10, an organic light-emitting layer 22, a spacer 15 and a cathode 11.

The flexible OLED display panel may further include a thin film encapsulation layer 12, a polarizer 13 and a cover plate 14.

The PET film 23 may be arranged at a non-display side of the flexible base substrate 4, so as to prevent the flexible OLED display panel from shrinking during the use thereof, and protect the OLED display panel.

By using the PET film 23, the flexible OLED display panel may have a relatively large thickness. When the flexible OLED display panel is adopted for fingerprint identification, due to the large thickness of the flexible OLED display panel, an optical path of a light beam reflected by each valley or ridge of the fingerprint may increase, so a large quantity of scattered light beams may be generated, and thereby the fingerprint identification accuracy may be adversely affected.

In the embodiments of the present disclosure, the collimation membrane 3 of the fingerprint identification module may allow the collimated light beam in the light beam reflected by the fingerprint to pass therethrough and prohibit the scattered light beam from passing therethrough, and each photosensitive sensor 2 may receive the collimated light beam passing through the collimation membrane 3 and identify the fingerprint in accordance with the collimated light beam. As a result, it is able to improve accuracy of fingerprint identification.

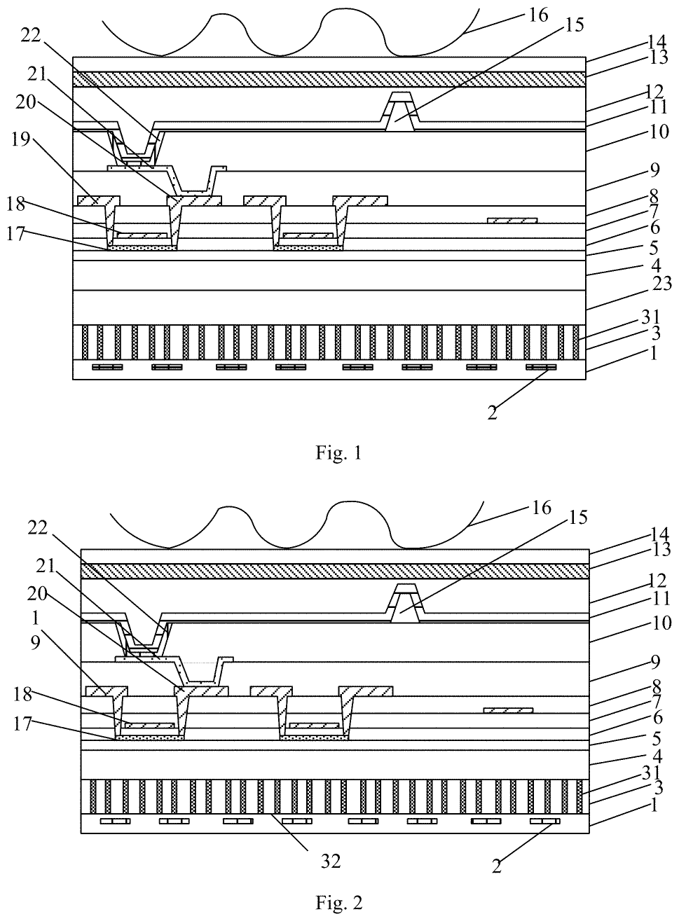

In some embodiments of the present disclosure, as shown in FIG. 2, different from the structure of the fingerprint identification panel in FIG. 1, the collimation membrane 3 may be reused as the PET film 23 (i.e., a support layer) of the flexible OLED display panel.

In FIG. 2, when the collimation membrane 3 is reused as the support layer of the flexible OLED display panel, so it is unnecessary to provide the PET film. At this time, it is able to reduce a thickness of the fingerprint identification panel, reduce the optical path of the light beam reflected by each valley or ridge of the fingerprint, reduce the loss of information about the light beam reflected by the valley or ridge, and increase an intensity of the light beam received by the photosensitive sensor, thereby to improve accuracy of fingerprint identification.

Usually, the PET film has a thickness of 70 μm to 100 μm, so through the structure in FIG. 2, it is able to reduce the thickness of the fingerprint identification panel by 70 μm to 100 μm.

During the fingerprint identification through the fingerprint identification panel, the light beam reflected by the valley or ridge of the fingerprint may pass through the cover plate 14, the polarizer 13, the thin film encapsulation layer 12, the cathode 11, the pixel definition layer 10, the polarization layer 9, the third insulation layer 8, the second insulation layer 7, the first insulation layer 6, the buffer layer 5 and the flexible base substrate 4 to the fingerprint identification module. Due to the optical path, the light beam has become a mixed light beam with mixed light information. Through the collimation membrane, it is able to screen out the scattered light beam in the reflected light beam, and collimate the light beam reflected by the valley or ridge at a side of the flexible base substrate 4 away from the collimation membrane 3. The collimated light beam may be received by the photosensitive sensor 2. Information about the light intensity sensed by the photosensitive sensor 2 may be subjected to the subsequent circuit treatment, data treatment and image treatment, so as to acquire information about the fingerprint.

In FIG. 2, after reducing the thickness of the PET film by 70 μm to 100 μm, it is able to increase the intensity of the light beam received by the photosensitive sensor 2, thereby to improve accuracy of fingerprint identification as well as definition of a fingerprint image.

In some embodiments of the present disclosure, the collimation membrane may include a plurality of light-shielding retainer walls, and a transparent material layer filled between two adjacent light-shielding retainer walls.

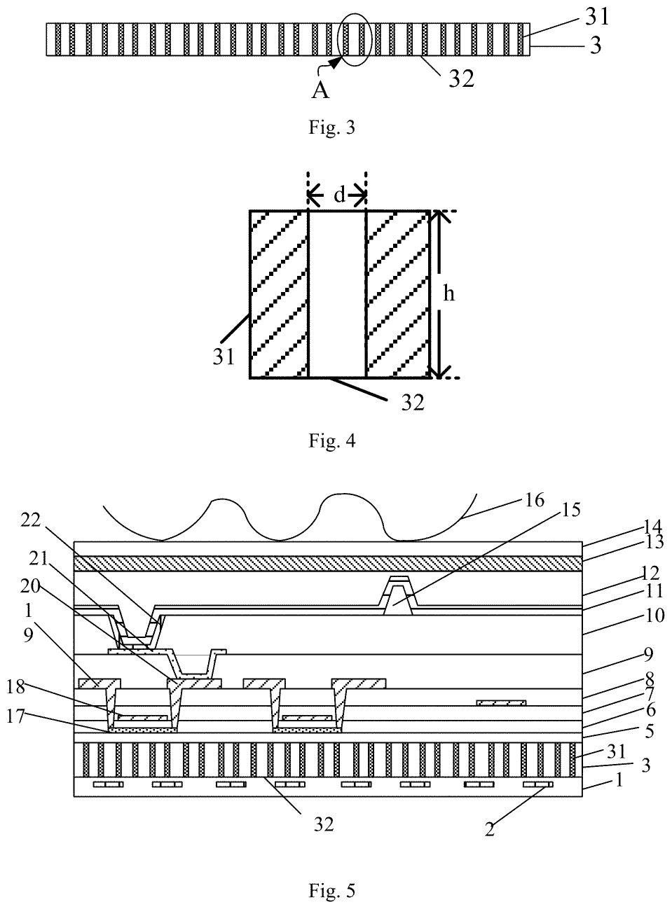

As shown in FIGS. 2 and 3, the collimation membrane 3 may include a plurality of light-shielding retainer walls 31 arranged in parallel with each other, and the transparent material layer 32 filled between two adjacent light-shielding retainer walls 31.

In some embodiments of the present disclosure, as shown in FIG. 3, each light-shielding retainer wall 31 may be of a strip-like shape.

In some embodiments of the present disclosure, each light-shielding retainer wall 31 may be made of a black matrix material, or any other black resin material, and the transparent material layer 32 made of a transparent material (e.g., a resin material of the spacer 15) may be filled between the light-shielding retainer walls 31.

During the attachment of the collimation membrane to the flexible display panel, a pressure may be applied to the collimation membrane. When no transparent material layer is filled between the adjacent light-shielding retainer walls, each light-shielding retainer wall may be tilted due to the pressure. At this time, a light transmittance of the collimation membrane may decrease and a collimation effect may be adversely affected. Hence, the transparent material layer may be filled between the adjacent light-shielding retainer walls, so as to prevent the light-shielding retainer wall from being tilted, thereby to ensure the fingerprint identification accuracy.

In some embodiments of the present disclosure, the transparent material layer 32 may have a height greater than or equal to a height of the light-shielding retainer wall 31.

When the height of the transparent material layer 32 is greater than or equal to the height of the light-shielding retainer wall 31, it is able to prevent the light-shielding retainer wall 31 from being tilted, thereby to ensure the fingerprint identification accuracy.

In some embodiments of the present disclosure, as shown in FIG. 4, in order to ensure the collimation effect, a ratio of a distance d between two adjacent light-shielding retainer walls 31 (i.e., the distance between two adjacent light-shielding retainer walls 31) to the height h of the light-shielding retainer wall 31 may be 1/10 to 1/7.

In some embodiments of the present disclosure, in order to support the flexible display panel through the collimation membrane 3 at a sufficient strength, as shown in FIG. 4, the collimation membrane 3 may have a thickness of 100 μm to 300 μm.

In some embodiments of the present disclosure, the thickness of the collimation membrane 3 may be equal to the height h of the light-shielding retainer wall 31.

In some embodiments of the present disclosure, as shown in FIG. 5, the collimation membrane of the fingerprint identification panel may be reused as the flexible base substrate and the support layer of the flexible display panel. The fingerprint identification panel in FIG. 5 differs from that in FIG. 2 in that the collimation membrane 3 is reused as the flexible base substrate and the support layer of the flexible display panel.

In FIG. 5, when the collimation membrane 3 is reused as the flexible base substrate and the support layer of the flexible OLED display panel, it is unnecessary to provide the flexible base substrate and the PET film. As a result, it is able to reduce the thickness of the fingerprint identification panel, reduce the optical path of the light beam reflected by each valley or ridge of the fingerprint, reduce the loss of information about the light beam reflected by the valley or ridge, and increase the intensity of the light beam received by the photosensitive sensor, thereby to improve accuracy of fingerprint identification as well as the definition of the fingerprint image.

In FIG. 5, during the fingerprint identification through the fingerprint identification panel, the light beam reflected by the valley or ridge of the fingerprint may pass through the cover plate 14, the polarizer 13, the thin film encapsulation layer 12, the cathode 11, the pixel definition layer 10, the polarization layer 9, the third insulation layer 8, the second insulation layer 7, the first insulation layer 6 and the buffer layer 5 to the fingerprint identification module. Due to the optical path, the light beam has become a mixed light beam having mixed light information. Through the collimation membrane, it is able to screen out the scattered light beam in the reflected light beam, and collimate the light beam reflected by the valley or ridge at a side of the flexible base substrate 4 away from the collimation membrane 3. The collimated light beam may be received by the photosensitive sensor 2. Information about the light intensity sensed by the photosensitive sensor 2 may be subjected to the subsequent circuit treatment, data treatment and image treatment, so as to acquire information about the fingerprint.

In FIG. 5, after the removal of the flexible base substrate and the PET film, it is able to increase the intensity of the light beam received by the photosensitive sensor 2, thereby to improve accuracy of fingerprint identification as well as the definition of the fingerprint image.

The present disclosure further provides in some embodiments a fingerprint identification method for the above-mentioned fingerprint identification panel, including: receiving, by the collimation membrane, a reflected light beam transmitted from the display panel, the reflected light beam being formed by a light beam emitted from the display panel and reflected by a finger; allowing, by a collimation membrane, a collimated light beam in the reflected light beam to pass therethrough, and shielding a scattered light beam in the reflected light beam; and receiving, by a photosensitive sensor, the collimated light beam, and identifying a fingerprint in accordance with the collimated light beam.

According to the embodiments of fingerprint identification method in the embodiments of the present disclosure, the collimation membrane of the fingerprint identification module may allow the collimated light beam to pass therethrough and prohibit the scattered light beam from passing therethrough, and each photosensitive sensor may receive the collimated light beam passing through the collimation membrane and identify the fingerprint in accordance with the collimated light beam. As a result, it is able to improve accuracy of fingerprint identification.

The present disclosure further provides in some embodiments a display device, including the above-mentioned fingerprint identification panel. The display device may be any product or member having a display function, e.g., television, display, digital photo frame, mobile phone or flat-panel computer.

In some embodiments of the present disclosure, the display device may further include a flexible circuit board, a printed circuit board and a back plate.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A fingerprint identification panel, comprising:
a display panel comprising a substrate and a display element arranged at one side of the substrate; and
a fingerprint identification module arranged at a side of the substrate away from the display element,
wherein the fingerprint identification module comprises a collimation membrane and photosensitive sensors;
the collimation membrane is configured to allow a collimated light beam in a reflected light beam to pass therethrough and prohibit a scattered light beam in the reflected light beam from passing therethrough;
the reflected light beam is formed by a light beam emitted from the display panel and reflected by a finger; and
each photosensitive sensor is configured to receive the collimated light beam and identity a fingerprint in accordance with the collimated light beam.

2. The fingerprint identification panel according to claim 1, wherein the display panel is a flexible display panel, and the substrate is a flexible substrate.

3. The fingerprint identification panel according to claim 2, wherein the collimation membrane is reused as at least a part of the flexible substrate.

4. The fingerprint identification panel according to claim 3, wherein the flexible substrate comprises a flexible base substrate and a support layer, and the collimation membrane is reused as the support layer or as the flexible base substrate and the support layer.

5. The fingerprint identification panel according to claim 4, wherein the flexible base substrate has a thickness of 15 μm to 25 μm, and the support layer has a thickness of 70 μm to 100 μm.

6. The fingerprint identification panel according to claim 2, wherein the flexible display panel further comprises a thin film encapsulation layer covering the display element, a polarizer arranged at a side of the thin film encapsulation layer away from the display element, and an encapsulation cover plate arranged at a side of the polarizer away from the thin film encapsulation layer.

7. The fingerprint identification panel according to claim 1, wherein the fingerprint identification module further comprises a flexible thin film, the photosensitive sensors are arranged on the flexible thin film in an array form, and the flexible thin film is attached to a side of the collimation membrane away from the flexible display panel.

8. The fingerprint identification panel according to claim 1, wherein the collimation membrane comprises a plurality of light-shielding retainer walls, and a transparent material layer filled between two adjacent light-shielding retainer walls.

9. The fingerprint identification panel according to claim 8, wherein the plurality of light-shielding retainer walls is arranged in parallel with each other.

10. The fingerprint identification panel according to claim 8, 9, wherein each of the plurality of light-shielding retainer walls is of a strip-like shape.

11. The fingerprint identification panel according to claim 8, wherein a height of the transparent material layer is greater than or equal to that of any light-shielding retainer wall.

12. The fingerprint identification panel according to claim 8, wherein a ratio of a distance between two adjacent light-shielding retainer walls to the height of each light-shielding retainer wall is 1/10 to 1/7.

13. The fingerprint identification panel according to claim 1, wherein the collimation membrane has a thickness of 100 μm to 300 μm.

14. The fingerprint identification panel according to claim 1, wherein the display panel is a non-flexible display panel.

15. A fingerprint identification method for the fingerprint identification panel according to claim 1, comprising:
transmitting, by the display panel, a reflected light beam to a collimation membrane, the reflected light beam being formed by a light beam emitted from the display panel and reflected by a finger;
allowing, by the collimation membrane, a collimated light beam in the reflected light beam to pass therethrough, and shielding a scattered light beam in the reflected light beam; and
receiving, by the photosensitive sensor, the collimated light beam, and identifying a fingerprint in accordance with the collimated light beam.

16. A display device, comprising the fingerprint identification panel according to claim 1.
